(19) United States
(12) Patent Application Publication
(10) Pub. No.: US 2026/0182300 A1
(43) Pub. Date: Jun. 25, 2026

(54) DEVICE RAIL GUIDE UNJAMMING SYSTEM

(71) Applicant: SKYWORKS SOLUTIONS, INC., Irvine, CA (US)

(72) Inventors: Enrico Marcelo Sy, Mexicali (MX); Alexis Antonio Uribe Grijalva, Mexicali (MX); Orlando Escobar Ruiz, Mexicali (MX); Rodrigo Angulo Lopez, Mexicali (MX)

(21) Appl. No.: 19/419,417

(22) Filed: Dec. 15, 2025

Related U.S. Application Data
(60) Provisional application No. 63/736,226, filed on Dec. 19, 2024.
(60) Provisional application No. 63/736,230, filed on Dec. 19, 2024.

(51) Int. Cl. H10P 72/30; H03K 5/00; H03K 7/08

(52) U.S. Cl. CPC H10P 72/3202; H03K 5/00006; H03K 7/08

(57) ABSTRACT

According to the present disclosure there is provided a control circuit for a packaged semiconductor chip rail guide tapper driving means, comprising a control signal generator configured to generate control signals at a control frequency, and a drive module arranged to receive the control signals and output drive signals to the driving means based on the control signals to drive a rail guide tapper to tap a rail guide at a tapping frequency corresponding to the control frequency.

### CROSS-REFERENCE TO RELATED APPLICATIONS

This application claims priority under 35 U.S.C. § 119(e) to U.S. Provisional Patent Application Ser. No. 63/736,230, titled “DEVICE RAIL GUIDE UNJAMMING SYSTEM”, filed Dec. 19, 2024, and to U.S. Provisional Patent Application Ser. No. 63/736,226, titled “SYSTEM AND METHOD FOR UNJAMMING DEVICE RAIL GUIDE”, filed Dec. 19, 2024, the entire content of each being incorporated herein by reference for all purposes.

### BACKGROUND

### Field

The present disclosure relates to systems and methods for unjamming a packaged semiconductor chip rail guide. Aspects and embodiments disclosed herein also relate to a device handling system for packaged semiconductor chips.

### Description of the Related Technology

Device rail guides are frequently implemented in production and assembly lines as a means for conveying products and components along the production line. For instance, rail guides may be used for passing packaged semiconductor chips from a packaged device input, then passing through the rail guide to the device picker to connect the device to a test site interface board. However, rail guides can be susceptible to the formation of jams where a product gets stuck within the rail guide and blocks the passage of the following products. Consequently, the production system automatically halts and triggers a jam alarm. The rail guide then requires manual unjamming by an operator to resume production operations. This results in undesirable periods of downtime for the production line.

Conventionally, this device jamming issue is mitigated by integrating the rail guide with vibrating mounts. These mounts are designed to oscillate at a fixed frequency and within specific time intervals, utilizing a sturdy vibrating solenoid mechanism. This setup ensures periodic vibration of the rail guide, thereby preventing product jams within the guide. However, in instances where the product is fragile, the use of vibrating mounts can result in damage to the product from the motion of the rail guide and product therein which is induced by the vibrating mount. This is particularly problematic when conveying packaged semiconductor chips where excessive vibration can easily crack the semiconductor die or other elements of the package. It is therefore desirable to prevent jams from developing in a rail guide while also preventing damage to the product being conveyed by the rail guide.

### SUMMARY

According to one embodiment there is provided a control circuit for a packaged semiconductor chip rail guide tapper driving means. The control circuit comprises a control signal generator configured to generate control signals at a control frequency, and a drive module arranged to receive the control signals and output drive signals to the packaged semiconductor chip rail guide driving means based on the control signals to drive a rail guide tapper to tap a rail guide at a tapping frequency corresponding to the control frequency.

In one example, the control signal generator is a square wave generator.

In one example, the control signal generator is further configured to adjust the control frequency of the control signals.

In one example, the control frequency is adjustable from 1 hertz to 50 hertz.

In one example, the control signal generator is further configured to adjust a duty cycle of the control signals.

In one example, the control signals have a voltage peak-to-peak value of 9.35 volts.

In one example, the drive module is a dual metal oxide semiconductor field effect transistor.

In one example, the drive module is further configured to perform pulse-width modulation on the control signals to output the drive signals.

In one example, the control circuit further comprises a step-down converter configured to reduce a voltage of power signals received by the step-down converter from a first voltage to a second voltage and provide the power signals at the second voltage to the control signal generator to generate the control signals at the control frequency based on the power signals at the second voltage.

In one example, the step-down converter is a buck converter.

In one example, the first voltage is 24 volts and the second voltage is 9 volts.

In one example, the step-down converter is configured to provide the power signals at the second voltage within a tolerance of 0.7 volts.

In one example, the control circuit further comprises an opto-coupler isolator coupled to the control signal generator and the drive module, said opto-coupler isolator being configured to receive the control signals from the control signal generator and either provide the control signals to the drive module when in a conducting state or block the control signals to the drive module when in a non-conducting state.

In one example, the control circuit further comprises an opto-coupler controller coupled to the opto-coupler isolator and configured to output an opto-coupler control signal to the opto-coupler isolator to cause the opto-coupler isolator to operate in the conducting state.

In one example, the opto-coupler controller is further configured to receive a user input and to output the opto-coupler control signal in response to the user input.

According to another embodiment there is provided a device rail unjamming system for a packaged semiconductor chip rail guide. The system comprises a tapper arranged to tap the rail guide from above the rail guide, a driving means coupled to the tapper, and a drive circuit configured to provide drive signals to the driving means to drive the tapper at a tapping frequency to unjam a packaged semiconductor within the rail guide.

In one example, the driving means is a solenoid valve.

In one example, the tapper is formed of an antistatic plastic material.

In one example, the system further comprises means for attaching to the rail guide.

In one example, the drive circuit is further configured to adjust the drive signals provided to the driving means to adjust the tapping frequency.

In one example, the tapping frequency is adjustable from 1 Hertz to 50 Hertz.

In one example, the drive circuit is further configured to adjust the drive signals provided to the driving means to adjust a tapping duty cycle of the tapper.

In one example, the drive circuit is further configured to adjust the drive signals provided to the driving means to adjust a tapping force of the tapper.

In one example, the drive signals are square wave signals.

According to another embodiment there is provided a method of unjamming a packaged semiconductor chip rail guide. The method comprises providing drive signals to a driving means coupled to a tapper to drive the tapper at a tapping frequency, and tapping the rail guide at the tapping frequency with the tapper from above the rail guide to unjam a packaged semiconductor chip within the rail guide.

In one example, the driving means is a solenoid valve.

In one example, the tapper is formed of an antistatic plastic material.

In one example, the method further comprises adjusting the drive signals provided to the driving means to adjust the tapping frequency.

In one example, the tapping frequency is adjustable from 1 hertz to 50 hertz.

In one example, the method further comprises adjusting the drive signals provided to the driving means to adjust a tapping duty cycle of the tapper.

In one example, the method further comprises adjusting the drive signals provided to the driving means to adjust a tapping force of the tapper.

In one example, the drive signals are square wave signals.

According to another embodiment there is provided a device handling system for packaged semiconductor chips. The system comprises a rail guide configured to receive a packaged semiconductor, and a tapping means coupled to the rail guide and configured to tap the rail guide from above the rail guide at a tapping frequency to unjam a packaged semiconductor within the rail guide.

In one example, the tapping means is further configured to adjust the tapping frequency.

In one example, the tapping means is further configured to adjust a tapping duty cycle and a tapping force of the tapper.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment,” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a schematic block diagram of a device rail unjamming system according to aspects and embodiments disclosed herein;

FIG. 2 is a schematic block diagram of a drive circuit according to aspects and embodiments disclosed herein;

FIG. 3 is a schematic diagram of a device handling system including a rail guide according to aspects and embodiments disclosed herein;

FIG. 4A is a schematic cross-section diagram of a device handling system including a rail guide and a tapper in contact with the rail guide according to aspects and embodiments disclosed herein; and

FIG. 4B is a schematic cross-section diagram of a device handling system including a rail guide and a tapper displaced above the rail guide according to aspects and embodiments disclosed herein.

### DETAILED DESCRIPTION

Aspects and embodiments described herein are directed to a device rail unjamming system for a packaged semiconductor chip rail guide to unjam a packaged semiconductor within the rail guide without causing damage to the packaged semiconductor. It will be appreciated that the embodiments and techniques discussed herein are both capable of unjamming packaged semiconductor chips and preventing jams from occurring.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

Rail guides, sometimes referred to as “guide rails,” are components frequently deployed in production lines and are configured to convey a product from one point in a production line to another. The rail guides align and support the product as it moves along the length of the production line and reduce the need for manual intervention to transfer products between production steps. Accordingly, rail guides are sometimes used in semiconductor fabrication production lines, for example, to transfer a packaged semiconductor chip from a testing stage to a final packaging stage of production.

Within a semiconductor fabrication production line, semiconductor packages are created when one or more discrete semiconductor devices are encased in a metal, plastic, glass, or ceramic casing. A semiconductor package, or “packaged semiconductor,” typically contains means for electrical connection between the semiconductor device, or die, and an external circuit. While the encasement provides some protection to the semiconductor device, the device is still susceptible to damage and therefore particular care should be taken to reduce the chance of damage to the device and thereby limit the failure rate of the production line as far as possible. Such semiconductor packages may be conveyed along a production with a rail guide.

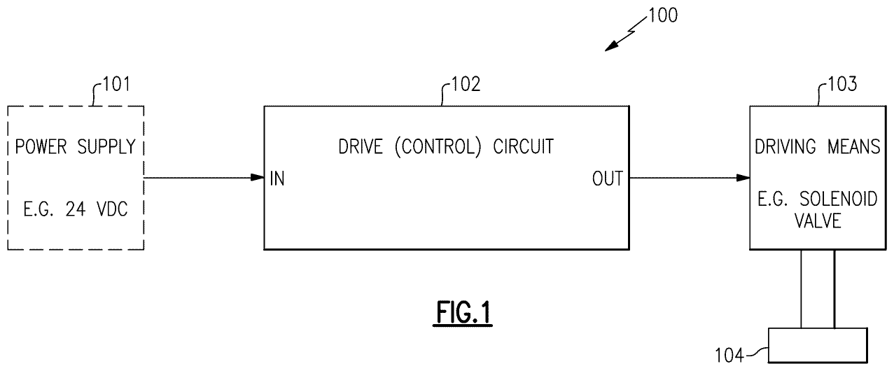

FIG. 1 is a schematic depiction of an exemplary device rail unjamming system 100 according to the aspects and embodiments disclosed herein, showing a drive circuit 102, a driving means 103, and a tapper 104. The drive circuit 102 is configured to provide drive signals to the driving means 103 coupled to the tapper 104 to drive the tapper 104 at a tapping frequency. Although it is not shown in FIG. 1, the tapper 104 is arranged to tap a rail guide from above the rail guide. In doing so, the tapper 104 makes contact with the rail guide, or “taps” from above and causes the rail guide to vibrate. The vibration of the rail guide will greatly reduce the chances of a semiconductor package jamming within the rail guide. In some embodiments the driving means 103 may be a solenoid valve to provide increased control over tapping frequency at which the tapper 104 taps the rail guide. A solenoid valve is an electromechanically actuated valve that comprises a solenoid, which is an inductive coil, and a valve body containing one or more orifices housing one or more plungers including or formed of a ferrimagnetic or ferromagnetic material. Upon energization, the solenoid generates a magnetic field that induces a linear motion for a controlled linear displacement of the plunger(s) with precision. In some embodiments the tapper 104 may be formed of an antistatic plastic material to avoid the build-up and discharge of static charge near or to the semiconductor packages within the rail guide. It should be noted that the term “tapper” used herein may refer to either a whole component that is driven by the driving means 103, or a portion of a whole component that is driven by the driving means 103 that makes contact with the rail guide, such as the tip. In some embodiments the system 100 may further comprise means for attaching to the rail guide. In some embodiments the system 100 may further comprise a power supply 101 or be couplable to a power supply 101 to provide power signals to the drive circuit 102. In some embodiments the power supply may be configured to supply 24 volts direct current (DC).

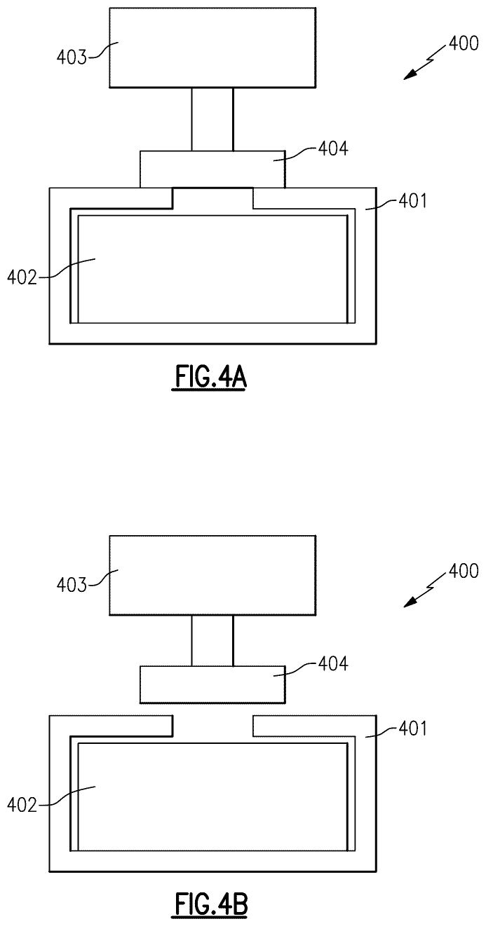

The configuration of FIG. 1 facilitates unjamming a packaged semiconductor within a rail guide by tapping the rail guide from above at a tapping frequency thereby stimulating vibrations in the rail guide which unjam the packaged semiconductor. Tapping the rail guide from above as opposed to continually vibrating the rail guide from below allows for gentler vibrations to be delivered to the rail guide while minimizing vibration, and therefore damage, of the packaged semiconductors. The term “tapping” is used here to describe the action of an object accelerating towards and subsequently contacting a surface. Such “tapping” may be a repeated action having a defined periodicity, force, and/or duty cycle. An example of the tapping action can be seen in FIGS. 4A and 4B showing the tapper in contact and apart from the rail guide surface.

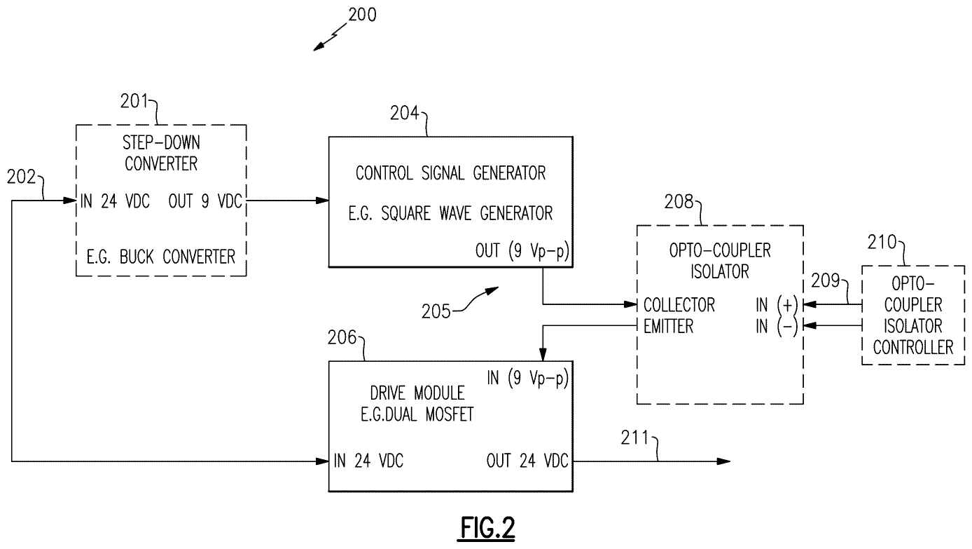

FIG. 2 is a schematic depiction of an exemplary drive circuit 200 according to the aspects and embodiments disclosed herein, showing a control signal generator 204 and a drive module 206. The drive circuit 200 may also be referred to as a “control circuit” herein and the terms may be used interchangeably. The control signal generator 204 is configured to generate control signals 205 at a control frequency which are provided to the drive module 206. It will be appreciated that the control signal generator 204 and drive module 206 may be directly coupled and therefore the control signals 205 are provided directly therebetween, or additional electrical components may be disposed between the control signal generator 204 and drive module 206 and the control signals 205 are provided from the control signal generator 204 to the drive module 206 via the additional electrical components. The drive module 206 is arranged to receive the control signals 205 and output drive signals 211 to a driving means (e.g., driving means 103) to drive a tapper (e.g., tapper 104) to tap a rail guide at a tapping frequency corresponding to the control frequency. The tapping frequency may be equal to the control frequency or may be a transform of the control frequency, for example, a multiplication or division thereof. In some embodiments, the control signal generator 204 may be a square wave generator. In some embodiments the control signals 205 may have a voltage peak-to-peak value of 9.35 volts.

In some embodiments the control signal generator 204 may be configured to adjust the control frequency of the control signals 205. By adjusting the control frequency the tapping frequency of the tapper is correspondingly adjusted. This is particularly advantageous as certain tapping frequencies may more effectively stimulate vibrations in the rail guide which in turn may more effectively unjam a jammed semiconductor package. For instance, certain tapping frequencies may stimulate a fundamental or harmonic natural resonance of the rail guide which will result in a larger amplitude of rail guide vibration and therefore more easily unjam a semiconductor package. This also means that only a single tapper may be utilized to stimulate a rail guide as opposed to requiring multiple vibrating devices distributed along a rail guide. However, every rail guide will have a unique resonant frequency as a result of manufacturing and installation. Furthermore, the properties of the packaged semiconductor chips being conveyed on the semiconductor package, such as size or quantity, will also affect the natural resonant frequency of the rail guide. Therefore, by facilitating an adjustable control frequency the drive circuit 200 can appropriately adjust the tapping frequency of the tapper to stimulate a natural resonance in an array of rail guides or in a rail guide that conveys a variety of different semiconductor packages with different properties. In some embodiments, the control signal generator 204 may adjust the control frequency of the control signals 205 in response to a user input. In doing so, an operator of the production line can appropriately adjust the tapping frequency depending on what frequency is most appropriate to unjam a specific semiconductor package, such as matching a natural resonant frequency. In some embodiments, the control frequency may be adjustable from 1 hertz to 50 hertz. In some embodiments the control signal generator 204 may be configured to adjust a duty cycle of the control signals 205 which will correspondingly alter a duty cycle of the tapping frequency. By doing so, it is possible to gain further control over the movement of the tapper, particularly the length of time the tapper is in contact with the rail guide. This facilitates greater control of the rail guide vibrations to enable more successful unjamming.

In some embodiments the drive module 206 may be a dual metal oxide semiconductor field effect transistor (MOSFET). In some embodiments the drive module 206 may be configured to perform pulse-width modulation on the control signals 205 to output the drive signals 211. The dual MOSFET may be configured to operate over a 0 to 20 kilohertz pulse-width modulation range to allow extremely fine switch control of the driving means. In such an arrangement, the dual MOSFET comprises two high-power field effect transistors, one of which is activated by control signals 205 from the control signal generator 204 and the other is activated by power signals 202 from a power supply (e.g., power supply 101), respectively. In some embodiments the power supply may provide 24 volts DC to the dual MOSFET to be provided to the driving means.

In some embodiments the drive circuit 200 may comprise a step-down converter 201 configured to reduce a voltage of power signals 202 from a first voltage to a second voltage and provide the power signals 202 at the second voltage to the control signal generator 204 to generate the control signals 205 based on the power signals 202. The inclusion of a step-down converter allows for effective voltage regulation within the drive circuit 200. In some embodiments the step-down converter may be a buck converter (DC-to-DC buck converter) to allow for high-efficiency voltage step down while boosting current, bypassing the conversion of surplus voltage into heat. Buck converters typically comprise high-fidelity inductors, resistors with a light-emitting diode (LED) output indicator, and high-grade solid-state capacitors which collectively filter out high-frequency noise and secure a stable signal output which is particularly advantageous for the fine control utilized to address the present technical problem. In some embodiments the first voltage may be 24 volts and the second voltage may be 9 volts. In some embodiments the step-down converter may be configured to provide the power signals 202 at the second voltage within a tolerance of 0.7 volts. By ensuring that the step-down converter (e.g., a buck converter) can tune the output within a tolerance of 0.7 volts, far greater control over the tapper can be attained, noting that the voltage of the control signal generator 204 may correspond to the force with which the tapper contacts the rail guide.

In some embodiments the drive circuit 200 may comprise an opto-coupler isolator 208 coupled to the control signal generator 204 and the drive module 206, said opto-coupler isolator 208 being configured to receive the control signals 205 and either provide the control signals 205 to the drive module 206 when in a conducting state or block the control signals 205 to the drive module 206 when in a non-conducting state. Opto-coupler isolators typically comprise an LED and a phototransistor. In this instance, the term “conducting state” refers to a state wherein the LED is switched on and the phototransistor is in a conductive state. Conversely, the term “non-conducting state” refers to a state wherein the LED is switched off and the phototransistor is non-conductive and therefore does not conduct, or “blocks,” any signals through it. The output of the control signal generator 204 may be coupled to a collector of the opto-coupler isolator 208 and the drive module 206 may be coupled to an emitter of the opto-coupler isolator 208. In some embodiments the drive circuit 200 may further comprise an opto-coupler controller 210 coupled to the opto-coupler isolator 208 and configured to output an opto-coupler controller control signal 209 to the opto-coupler isolator 208 to cause the opto-coupler isolator 208 to operate in the conducting state. By implementing an opto-coupler isolator 208, it is possible to control the output of the drive circuit 200, for example, with the opto-coupler controller 210, with full electrical isolation between the controller 210 and control signal generator 204. This prevents electrical loading on the opto-coupler controller 210 which could impact the performance of the drive circuit 200. When in the conducting state, the opto-coupler isolator 208 provides the control signals 205 to the driving module 206. In some embodiments, the opto-coupler controller 210 may be configured to receive a user input and to output the opto-coupler control signal 209 in response to the user input.

The arrangement of FIG. 2 allows for fine output and control of the frequency at which a tapper taps a rail guide. In doing so, the system can unjam packaged semiconductors with minimal damage and also target tapping frequencies which more successfully unjam the packaged semiconductors.

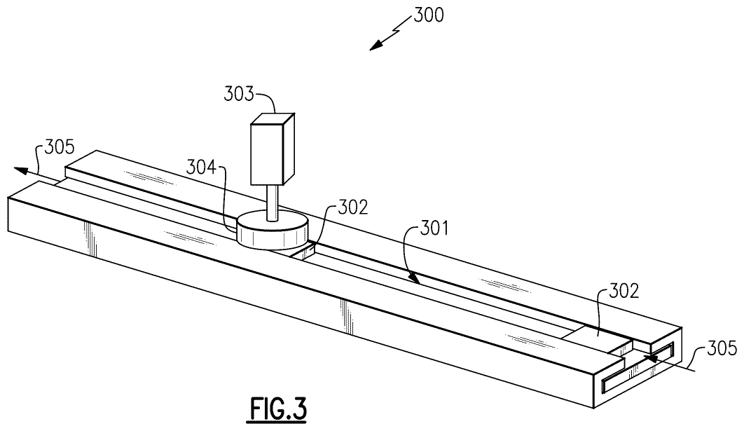

FIG. 3 is a schematic depiction of an exemplary device handling system 300 according to aspects and embodiments disclosed herein, showing a rail guide 301 and devices 302 travelling within the rail guide 301 in an output direction 305. The rail guide 301 is tapped at a tapping frequency by a tapper 304 (which may correspond to tapper 104) and is driven by a driving means 303 (which may correspond to driving means 103). In some embodiments, the driving means 303 is mechanically secured above the rail guide 301 by one or more brackets extending between sides of the driving means 303 and the rail guide 301 and coupled to the sides of the driving means 303 and the rail guide 301 by an adhesive and/or one or more fasteners such as screws, bolts, clips, hook and loop fasteners, or other fasteners known in the art. One example of a bracket 405 is illustrated in FIGS. 4A and 4B.

The devices 302 travel within the rail guide 301 in the output direction 305 and can get stuck, for instance if the device 302 rotates slightly and catches on an inner wall of the rail guide. By tapping the rail guide 301 with the tapper 304 at a tapping frequency, the tapper 304 can vibrate the rail guide and in turn dislodge the jammed device 302. While the present system is suitable for unjamming packaged semiconductor chips, it is conceivable that it would also be suitable for other fragile devices.

FIG. 4A is a schematic cross-section of a device handling system 400 according to aspects and embodiments disclosed herein, showing a rail guide 401 and device 402 travelling within the rail guide 401. The device handling system 400 may correspond to device handling system 300. The diagram shows a tapper 404 in contact with the rail guide 401 from above when driven by a driving means 403. By tapping the rail guide 401 in this manner, vibrations are stimulated in the rail guide 401 to unjam a device 402 jammed therein.

FIG. 4B is a schematic cross-section of the device handling system 400 according to aspects and embodiments disclosed herein, showing the rail guide 401 and device 402 travelling within the rail guide 401. The diagram shows tapper 404 when it is not in contact with the rail guide 401. This may be when the driving means is not receiving drive signals (e.g., drive signals 211).

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the aspects and embodiments disclosed herein. Accordingly, the foregoing description and drawings are by way of example only, and the scope of the aspects and embodiments disclosed herein should be determined from proper construction of the appended claims, and their equivalents.

It is to be appreciated that embodiments of the methods and apparatuses discussed herein are not limited in application to the details of construction and the arrangement of components set forth in the following description or illustrated in the accompanying drawings. The above detailed description of certain embodiments is not intended to be exhaustive or to limit the aspects and embodiments disclosed herein to the precise form disclosed above. The methods and apparatuses are capable of implementation in other embodiments and of being practiced or of being carried out in various ways. Accordingly, the examples of specific implementations provided herein are for illustrative purposes only and are not intended to be limiting. While specific embodiments of, and examples for, the aspects and embodiments disclosed herein are described above for illustrative purposes, various equivalent modifications are possible within the scope of the aspects and embodiments disclosed herein, as those ordinary skilled in the relevant art will recognize in view of the disclosure herein.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The words “coupled” or connected,” as generally used herein, refer to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The aspects and embodiments disclosed herein can be applied to other systems, not necessarily the systems described above. The elements and acts of the various embodiments described above can be combined to provide further embodiments.

While certain embodiments of the aspects and embodiments disclosed herein have been described, these embodiments have been presented by way of example only, and are not intended to limit the scope of the disclosure. Indeed, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A control circuit for a packaged semiconductor chip rail guide tapper driving means, comprising:
a control signal generator configured to generate control signals at a control frequency; and
a drive module arranged to receive the control signals and output drive signals to the packaged semiconductor chip rail guide driving means based on the control signals to drive a rail guide tapper to tap a rail guide at a tapping frequency corresponding to the control frequency.

2. The control circuit of claim 1 wherein the control signal generator is a square wave generator.

3. The control circuit of claim 1 wherein the control signal generator is further configured to adjust the control frequency of the control signals.

4. The control circuit of claim 1 wherein the control signal generator is further configured to adjust a duty cycle of the control signals.

5. The control circuit of claim 1 wherein the drive module is a dual metal oxide semiconductor field effect transistor.

6. The control circuit of claim 1 wherein the drive module is further configured to perform pulse-width modulation on the control signals to output the drive signals.

7. The control circuit of claim 1 further comprising a step-down converter configured to reduce a voltage of power signals received by the step-down converter from a first voltage to a second voltage and provide the power signals at the second voltage to the control signal generator to generate the control signals at the control frequency based on the power signals at the second voltage.

8. The control circuit of claim 7 wherein the step-down converter is a buck converter.

9. The control circuit of claim 1 further comprising an opto-coupler isolator coupled to the control signal generator and the drive module, said opto-coupler isolator being configured to receive the control signals from the control signal generator and either provide the control signals to the drive module when in a conducting state or block the control signals to the drive module when in a non-conducting state.

10. The control circuit of claim 9 further comprising an opto-coupler controller coupled to the opto-coupler isolator and configured to output an opto-coupler control signal to the opto-coupler isolator to cause the opto-coupler isolator to operate in the conducting state.

11. The control circuit of claim 10 wherein the opto-coupler controller is further configured to receive a user input and to output the opto-coupler control signal in response to the user input.

12. A device rail unjamming system for a packaged semiconductor chip rail guide, comprising:
a tapper arranged to tap the rail guide from above the rail guide;
a driving means coupled to the tapper; and
a drive circuit configured to provide drive signals to the driving means to drive the tapper at a tapping frequency to unjam a packaged semiconductor within the rail guide.

13. The system of claim 12 wherein the driving means is a solenoid valve.

14. The system of claim 12 wherein the tapper is formed of an antistatic plastic material.

15. The system of claim 12 further comprising means for attaching to the rail guide.

16. The system of claim 12 wherein the drive circuit is further configured to adjust the drive signals provided to the driving means to adjust the tapping frequency.

17. The system of claim 16 wherein the tapping frequency is adjustable from 1 hertz to 50 hertz.

18. The system of claim 12 wherein the drive circuit is further configured to adjust the drive signals provided to the driving means to adjust a tapping duty cycle of the tapper.

19. The system of claim 12 wherein the drive circuit is further configured to adjust the drive signals provided to the driving means to adjust a tapping force of the tapper.

20. A method of unjamming a packaged semiconductor chip rail guide, said method comprising:
providing drive signals to a driving means coupled to a tapper to drive the tapper at a tapping frequency; and
tapping the rail guide at the tapping frequency with the tapper from above the rail guide to unjam a packaged semiconductor chip within the rail guide.
